(19) United States
(12) Patent Application Publication
(10) Pub. No.: US 2006/0214654 A1
(43) Pub. Date: Sep. 28, 2006

(54) [CONDUCTING STRUCTURE OF A METER]

(75) Inventor: Hsu-Ming Liu, TAIPEI (TW)

Correspondence Address: TRISCO TECHNOLOGY CORP., P.O. BOX 108-00403, TAIPEI, TW

(73) Assignee: TRISCO TECHNOLOGY CORP., Taipei City (TW)

(21) Appl. No.: 10/907,280

(22) Filed: Mar. 28, 2005

(51) Int. Cl. G01R 1/04

(52) U.S. Cl. 324/156

(57) ABSTRACT

A conducting structure used in a meter is disclosed to include a plurality of electrically conducting support rods mounted inside the casing of the meter to support circuit boards of the meter at different elevations and to electrically connect the circuit boards to one another for transmission of signal and power.

### BACKGROUND OF THE INVENTION

1. Field of the Invention

The present invention relates to a meter and more specifically, to the conducting structure of a meter.

2. Description of the Related Art

A variety of meters and gauges are known for measuring the amount or speed of a fluid or gas, or for indicating direction or time. For example, a motor vehicle generally has a fuel indicator/gas gauge to indicate the amount of fuel oil, an oil pressure gauge to indicate the pressure of fuel oil, an engine temperature gauge to indicate engine temperature, a tachometer to measure engine speed, and an odometer to measure the distance traveled by the vehicle. In additional to vehicle internal meters/gauges, a car driver may attach a meter to the inside of the car for car performance setup indication. For example, a car driver may install an attached meter for setting up a speed limit. When the speed of the car surpassed the setup value, the attached meter immediately gives a warning signal to the car driver.

When using a meter in a car, the meter must be electrically connected to the internal circuit of the car to receive signal and power from the car. Therefore, a meter for use in a car must have a signal line and a power line for receiving signal and power from the car. A conventional meter A, as shown in FIG. 11, has circuit boards A2 mounted in the inside chamber A1, and electric wires B connected between the circuit boards A2. This design of meter A has drawbacks as follows.

1. Because a number of electric wires are used and connected to the circuit boards, the electric wires occupy much internal space and may be mixed up in a tangle.

2. The tangled electric wires may affect transmission of signal, causing signal or power interruption.

3. Because a number of electric wires are provided between the circuit boards, the installation procedure of the meter is complicated.

Therefore, it is desirable to provide a meter that eliminates the aforesaid drawbacks.

### SUMMARY OF THE INVENTION

The present invention has been accomplished under the circumstances in view. According to one aspect of the present invention, the conducting structure is used in a meter, comprising a plurality of electrically conducting support rods mounted inside the casing of the meter to support circuit boards of the meter at different elevations and to electrically connect the circuit boards to one another for transmission of signal and power. Because the invention uses metal conducting support rods to support the circuit boards and to electrically connect the circuit boards to one another instead of electric wires, the installation of the meter is simplified, saving much installation time and labor. Further, the electrically conducting support rods can be made of copper, nickel cast iron, aluminum, or zinc.

### BRIEF DESCRIPTION OF THE DRAWINGS

FIG. 1 is an elevational view of a meter according to the present invention.

FIG. 2 is an exploded view of the meter according to the present invention.

FIG. 3 is a sectional side view of the meter according to the present invention.

FIG. 4 is a top plain view of the present invention, showing the arrangement of the first support rods at the circuit boards.

FIG. 5 is an exploded view of an alternate form of the meter according to the present invention.

FIG. 6 is a sectional side view of the meter shown in FIG. 5.

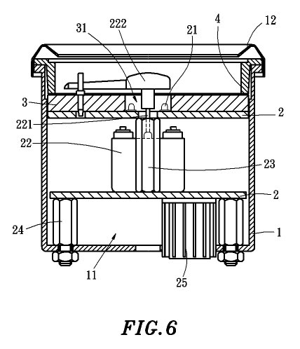

FIG. 7 is a top plain view of the meter shown in FIG. 5, showing the arrangement of the first support rods at the circuit boards.

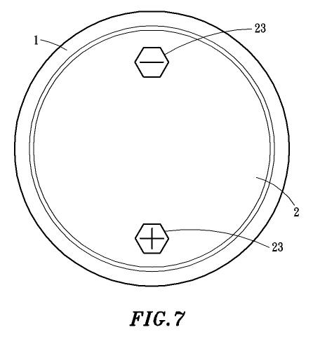

FIG. 8 is an exploded view of another alternate form of the meter according to the present invention.

FIG. 9 is a top plain view of the meter shown in FIG. 8, showing the arrangement of the first support rods at the circuit boards.

FIG. 10 is a sectional side view of still another alternate form of the meter according to the present invention.

FIG. 11 is a sectional side view of a meter according to the prior art.

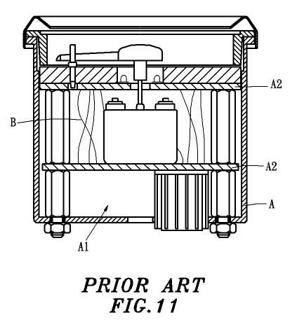

### DETAILED DESCRIPTION OF THE PREFERRED EMBODIMENT

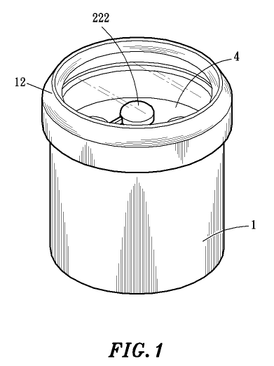

Referring to FIGS. 1˜3, a meter in accordance with one embodiment of the present invention is shown comprising a casing 1, circuit board unit, a light guide board 3, and a faceplate 4.

The casing 1 is a hollow member defining an accommodating chamber 11 and covered with a glass cover 12.

The aforesaid circuit board unit according to the present preferred embodiment is provided inside the casing 1, comprising two circuit boards 2, four first support rods 23 connected between the two circuit boards 2, a mini motor 22 vertically mounted on the bottom one of the two circuit boards 2 at the center and having an output shaft 221 vertically upwardly inserted through (the center through hole of) the top one of the two circuit boards 2 and fixedly fastened with a pointer 222, a plurality of light emitting elements, for example, LEDs (light emitting diodes) 21 installed in the top one of the circuit boards 2 and controllable to give off light, two second support rods 24 that support the bottom one of the two circuit boards 2 above the bottom wall of the accommodating chamber 11 of the casing 1, and a power socket 25 mounted in the bottom wall of the casing 1.

The light guide board 3 is a flat member made from transmittive material, having a center opening 31 extending through the top and bottom sides thereof.

The faceplate 4 is a hollow member made from transmittive material and marked with graduations.

During installation, the aforesaid circuit board unit is mounted inside the accommodating chamber 11 of the casing 1 and supported above the bottom wall of the casing 1 by the second support rods 24, keeping the power socket 25 extended to the outside of the casing 1, and then the light guide board 3 is mounted on the top one of the circuit boards 2, keeping the LEDs 21 suspending in the center opening 31 of the light guide board 3, and then the faceplate 4 is mounted on the light guide 3, keeping the output shaft 221 of the mini motor 22 inserted through the top one of the circuit boards 2, the center opening 31 of the light guide board 3 and the faceplate 4, and then the pointer 222 is fixedly fastened to the free end of the output shaft 221 of the mini motor 22 and suspending right above the LEDs 21, and then the glass cover 12 is capped on the casing 1.

The aforesaid four first support rods 23 and second support rods 24 are metal conducting rods made of for example, copper, nickel cast iron, aluminum, or zinc.

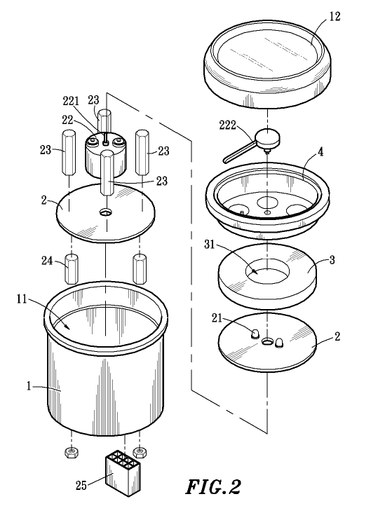

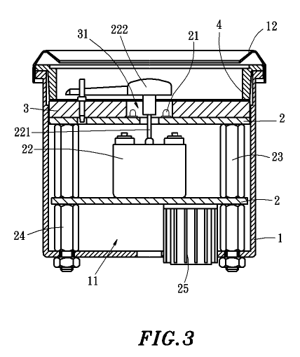

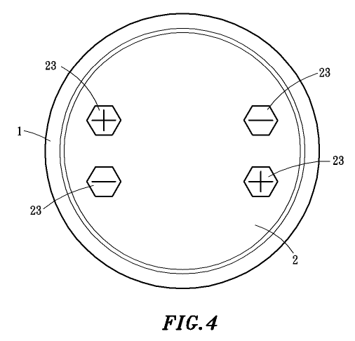

Referring to FIG. 4 and FIGS. 2 and 3 again, the first support rods 23 include two opposite positive conducting rods and two opposite negative conducting rods. The negative conducting rods are respectively connected between negative pole contacts of the circuit boards 2 to support the circuit boards 2 in place and to keep the circuit boards 2 spaced from each other at a distance and to form with the second support rods 24 a grounding circuit. The positive conducting rods are respectively electrically connected between positive pole contacts of the circuit boards 2 for transmission of signal and power.

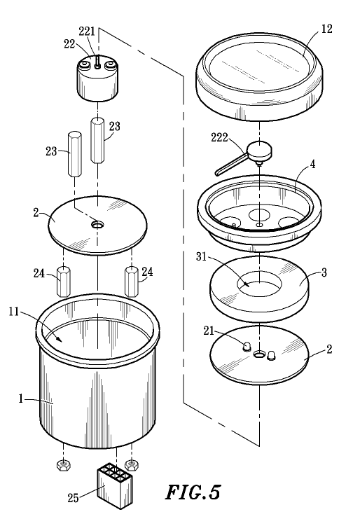

FIGS. 5˜7 show an alternate form of the present invention. This embodiment is substantially similar to the embodiment shown in FIGS. 1˜4 with the exception of the number of the support rods. According to this embodiment, two first support rods 23 are vertically connected between the two circuit boards 2 at two sides, and two second support rods 24 are bilaterally mounted inside the casing 1 to support the bottom one of the two circuit boards 2 above the bottom wall of the accommodating chamber 11 of the casing 1. The first support rods 23 are metal conducting rods including one positive conducting rod for transmission of signal and power and one negative conducting rod for a grounding circuit and respectively connected between the positive pole contacts and negative pole contacts of the circuit boards 2. The second support rods 24 are metal conducting rods including one positive conducting rod electrically connected between one positive pole contact of the bottom one of the two circuit boards 2 and the positive pole contact of the power socket 25 and one negative conducting rod electrically connected between one negative pole contact of the bottom one of the two circuit boards 2 and the negative pole contact of the power socket 25.

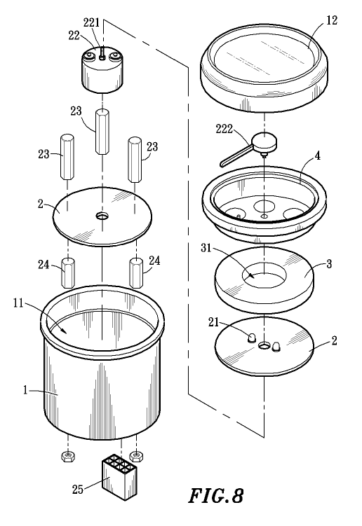

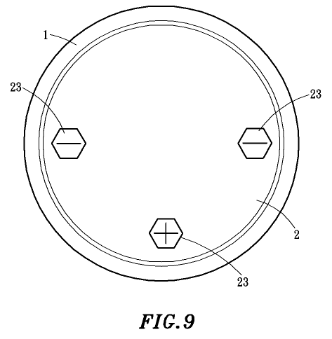

FIGS. 8 and 9 show another alternate form of the present invention. According to this embodiment, three first support rods 23 are vertically and equiangularly connected between the two circuit boards 2, and two second support rods 24 are bilaterally mounted inside the casing 1 to support the bottom one of the two circuit boards 2 above the bottom wall of the accommodating chamber 11 of the casing 1. The first support rods 23 are metal conducting rods including one positive conducting rod for transmission of signal and power and two negative conducting rods for a grounding circuit and respectively connected between the positive pole contacts and negative pole contacts of the circuit boards 2. The second support rods 24 are metal conducting rods including one positive conducting rod electrically connected between one positive pole contact of the bottom one of the two circuit boards 2 and the positive pole contact of the power socket 25 and one negative conducting rod electrically connected between one negative pole contact of the bottom one of the two circuit boards 2 and the negative pole contact of the power socket 25.

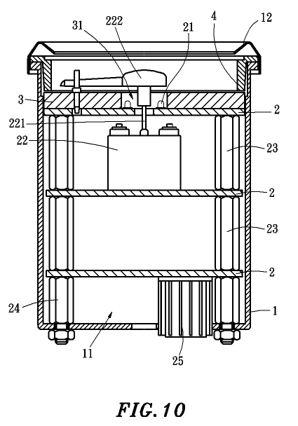

FIG. 10 shows still another alternate form of the present invention. According to this embodiment, three circuit boards 2 are arranged inside the casing 1 at different elevations, a plurality of first support rods 23 are respectively vertically connected between each two circuit boards 2, and a plurality of second support rods 24 are mounted inside the casing 1 to support the bottom one of the circuit boards 2 above the bottom wall of the accommodating chamber 11 of the casing 1. The first support rods 23 are metal conducting rods including positive conducting rods for transmission of signal and power and negative conducting rods for a grounding circuit and respectively connected to the positive pole contacts and negative pole contacts of the circuit boards.

As indicated above, the conducting structure of a meter according to the present invention has the features as follows.

1. The support rods are metal conducting rods used to support the circuit boards and to electrically connect the circuit boards for transmission of signal and power, saving much space between the circuit boards for other parts.

2. The support rods are metal conducting rods to ensure positive transmission of power and signal without interruption.

3. Using support rods to support and electrically connect circuit boards simplifies the installation, thereby saving much installation time and labor.

A prototype of conducting structure of a meter has been constructed with the features of FIGS. 1˜10. The conducting structure functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A conducting structure used in a meter, said meter comprising a casing, a plurality of circuit boards arranged inside said casing at different elevations, a faceplate marked with graduations and mounted inside said casing above said circuit boards, a mini motor mounted in one said circuit board, said mini motor having an output shaft vertically upwardly extending through a center through hole of said faceplate, and a pointer fixedly fastened to the output shaft of said mini motor above said faceplate and movable with the output shaft of said mini motor relative to said faceplate to point out the graduations at said faceplate, the conducting structure comprising a plurality of electrically conductive support rods respectively connected between positive pole contacts and negative pole contacts of said circuit boards to support said circuit boards on one above another and to electrically connect said circuit boards to one another.

2. The conducting structure as claimed in claim 1, wherein said electrically conductive support rods are metal rods.

3. The conducting structure as claimed in claim 2, wherein said metal rods are made of copper.

4. The conducting structure as claimed in claim 2, wherein said metal rods are made of nickel cast iron.

5. The conducting structure as claimed in claim 2, wherein said metal rods are made of aluminum.

6. The conducting structure as claimed in claim 2, wherein said metal rods are made of zinc.
